(19) United States
(12) Patent Application Publication
(10) Pub. No.: US 2016/0181380 A1
(43) Pub. Date: Jun. 23, 2016

(54) Semiconductor Device Metal-Insulator-Semiconductor Contacts with Interface Layers and Methods for Forming the Same

(71) Applicants: Intermolecular Inc., San Jose, CA (US); Global Foundries, Inc.

(72) Inventors: Amol Joshi, Sunnyvale, CA (US); Sean Barstow, San Jose, CA (US); Paul Besser, Sunnyvale, CA (US); Ashish Bodke, San Jose, CA (US); Guillaume Bouche, Albany, NY (US); Nobumichi Fuchigami, Sunnyvale, CA (US); Zhendong Hong, San Jose, CA (US); Shaoming Koh, Loyang View (SG); Albert Sanghyup Lee, Cupertino, CA (US); Salil Mujumdar, San Jose, CA (US); Abhijit Pethe, San Jose, CA (US); Mark Victor Raymond, Schenectady, NY (US)

(21) Appl. No.: 14/576,597

(22) Filed: Dec. 19, 2014

(51) Int. Cl. H01L 29/417; H01L 21/285; H01L 29/66; H01L 21/02; H01L 29/45; H01L 29/78

(52) U.S. Cl. CPC H01L 29/41758; H01L 29/452; H01L 29/456; H01L 29/78; H01L 29/66568; H01L 29/66522; H01L 21/02186; H01L 21/02362; H01L 21/2855; H01L 21/28556; H01L 21/28568; H01L 21/28575

(57) ABSTRACT

Embodiments provided herein describe systems and methods for forming semiconductor devices. A semiconductor substrate is provided. A source region and a drain region are formed on the semiconductor substrate. A gate electrode is formed between the source region and the drain region. A contact is formed above at least one of the source region and the drain region. The contact includes an insulating layer formed above the semiconductor substrate, an interface layer formed above the insulating layer, and a metallic layer formed above the interface layer. The interface layer is operable as a barrier between a material of the insulating layer and a material of the metallic layer, reduces the electrical resistance between the material of the insulating layer and the material of the metallic layer, or a combination thereof.

### TECHNICAL HELD

The present invention relates to semiconductor devices, such as transistors. More particularly, this invention relates to metal-insulator-semiconductor (MIS) contacts for semiconductor devices and methods for forming such contacts and semiconductor devices.

### BACKGROUND

As manufacturers strive to meet current demands for semiconductor device performance, the interfaces between layers or components within the devices are becoming increasingly important and are currently inhibiting the optimization of device performance. One example of such an interface is that between the source and drain regions of metal-oxide-semiconductor field-effect transistors (MOSFETs) and the contacts formed to make electrical connections to them.

When metals are directly deposited on a semiconductor substrate (e.g., silicon) to form contacts for devices, the Fermi level of the metal typically gets pinned in such a way that it is favorable for lowering contact resistivity on either N-type or P-type, but unfavorable for the other. In the case of silicon, the Fermi level for most of the metals gets pinned 0.66 eV below the conduction band. For making low resistivity contacts to N-type silicon, a low work function metal is desired, while contacts to P-type silicon generally require high work function metals. Insulators, such as titanium oxide, have been inserted between the metal and the semiconductor material (i.e., a MIS contact) to de-pin the Fermi level. However, in practice, the de-pinning does not work well for reactive metals, such as titanium. These metals can affect the composition of insulator and render de-pinning ineffective.

Alternatively, other conductors, such a titanium nitride and nickel, may be used which are less reactive with the insulating material. Although this allows appropriate de-pinning to be achieved, the resistance of the stack of materials, particularly the insulating material, may limit the applications of such contacts.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a substrate according to sonic embodiments.

FIG. 2 is a cross-sectional view of the substrate of FIG. 1 with an insulating layer formed above.

FIG. 3 is a cross-sectional view of the substrate of FIG. 2. with an interface layer formed above the insulating layer.

FIG. 4 is a cross-sectional view of the substrate of FIG. 3 with a metallic layer formed above the insulating layer.

FIG. 5 is a cross-sectional view of a substrate with a semiconductor device formed above.

FIG. 6 is a graph illustrating the Schottky barrier height for various stacks of materials.

FIG. 7 is a graph illustrating the series resistance of the stacks of materials of FIG. 6.

FIG. 8 is flow chart of a method for forming a semiconductor device according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims, and numerous alternatives, modifications, and equivalents are encompassed. Numerous specific details are set forth in the following description in order to provide a. thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Embodiments described herein provide metal-insulator-semiconductor (MIS) contacts for semiconductor devices, such as transistors. In sonic embodiments, a thin (e.g., 0.1-2.0 nm) “interface” layer is firmed between the insulating material and the conductive material/metal of the MIS contact. The interface layer may be formed using a deposition method, such as physical vapor deposition (PVD), while in some embodiments, the interface layer is formed using a plasma treatment performed on the upper surface of the insulating material.

In some embodiments, when the metal is reactive with the insulating material, the interface layer serves as a barrier to protect the insulating material and thus preserve the de-pinning effect of the MIS contact. As an example, when the insulating material is titanium oxide and the reactive metal is titanium, the interface layer may include titanium nitride and/or nickel deposited on the insulating layer using PVD, atomic layer deposition (ALD), etc. As another example of a barrier interface layer, the top surface of the insulating material may be exposed to a plasma, such as a nitrogen plasma, to form the barrier interface layer within the upper-most portion of the insulating material (e.g., a thin layer of nitrogen-doped titanium oxide).

In some embodiments, when the metal is not reactive with the insulating material and would otherwise result in a contact with an undesirably high resistance, the interface layer essentially lowers the resistance of the stack. As an example, when the insulating material is titanium oxide and the non-reactive metal is titanium nitride or nickel, the interface layer may include titanium and/or aluminum

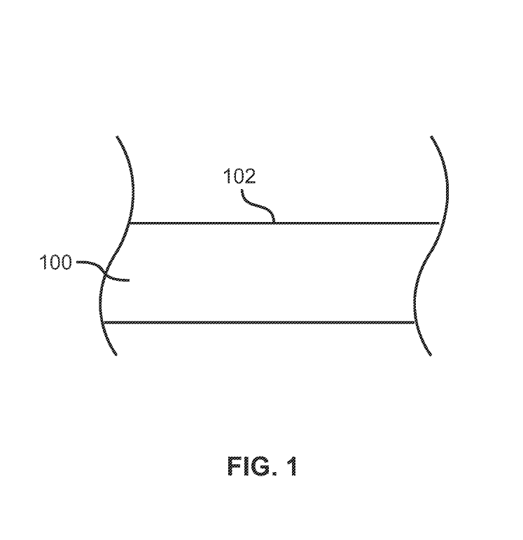

FIGS. 1-5 illustrate a method for forming a semiconductor device according to some embodiments. Referring to FIG. 1, a substrate 100 is provided. In some embodiments, the substrate 100 includes (or is made of) a semiconductor material, such as silicon, germanium, and/or a “IH-V” semiconductor material, such as gallium arsenide. The substrate 100 has an upper surface 102 and a thickness (not shown) of, for example, between about 200 micrometers (μm) and about 400 μm.

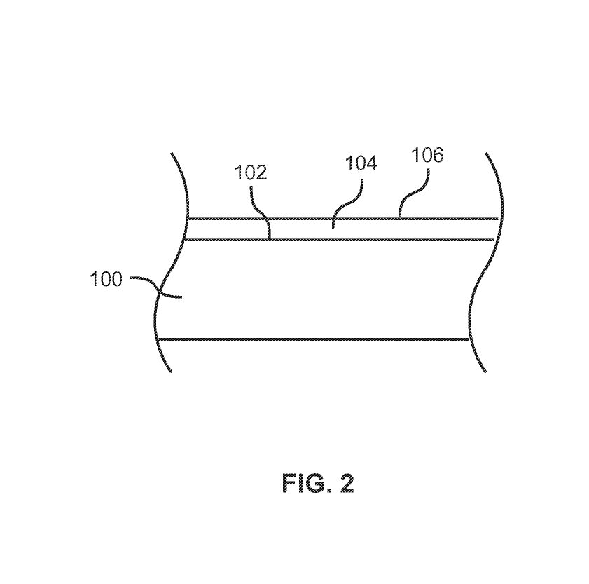

As shown in FIG. 2, an insulating layer 104 is formed above (e.g., on) the upper surface 102 of the substrate. In some embodiments, the insulating layer 104 includes (or is made of) an insulating material such as metal oxide or a nitride, such as titanium oxide, hathium oxide, aluminum oxide, zirconium oxide, silicon oxide, silicon nitride, silicon oxynitride, or a combination thereof The insulating layer 104 has an upper surface 106 and a thickness of, fir example, between about 3.0 nanometers and about 5.0 nm. The insulating layer 104 be formed using any suitable deposition method, such as physical vapor deposition (PVD), atomic layer deposition (ALD), plasma-enhanced atomic layer deposition (PEALD), chemical vapor deposition (CVD), plasma-enhanced chemical vapor deposition (PECVD), or a combination thereof.

Although not shown, it should be understood that the formation of the insulating layer 104 (as well as that of the other layers/components described below) may be performed in combination with a photolithography/etching process, as is commonly understood. As a result, the insulating layer 104 may be formed only above selected portions of the substrate 100.

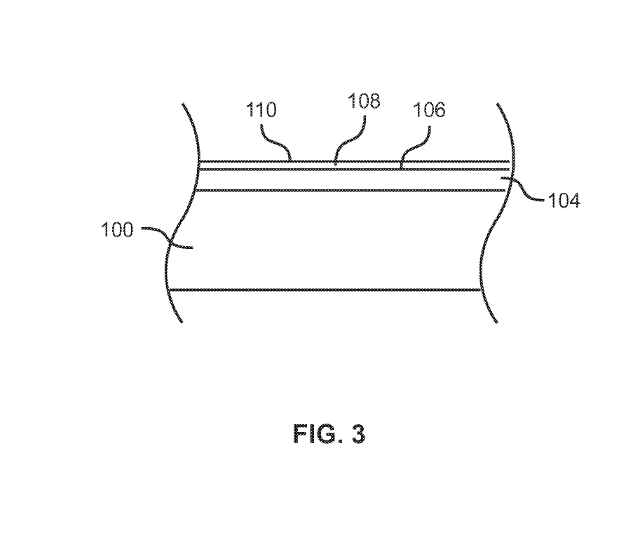

Referring to FIG. 3, an interface layer 108 is formed above (e.g., on) the upper surface 106 of the insulating layer 104. The material(s) and/or process(es) used to form the interface layer 108 may vary depending on, for example, the material(s) that are used to form the insulating layer 104 and the metallic layer (described below). The interface layer 108 may include (or be made of) titanium, titanium nitride, aluminum, nitrogen-doped titanium oxide, or a combination thereof. In some embodiments, the interface layer 108 is formed by depositing a material (e.g., titanium nitride or titanium) on the upper surface 106 of the insulating layer 104 and has a thickness of, for example, between about 0.5 nm and about 2 nm. For example, the interface layer 108 may be deposited using, for example, PVD, ALD, REAM, CND, PECVD, or a combination thereof.

However, in some embodiments, the interface layer 108 is formed by performing a plasma treatment on the upper surface 106 of the insulating layer 104. An example of such a plasma treatment is an exposure to nitrogen radicals (e.g., using a remote plasma source, using between about 1.5 kilowatts (kW) and about 2.0 kW of power, with a nitrogen flow rate of about 120 standard cubic centimeters per minute (sccm)). In some embodiments, the interface layer is formed by exposing a titanium oxide insulating layer (e.g., insulating layer 104) to nitrogen radicals which causes a thin layer (e.g., 0.1-0.5 nm) of nitrogen-doped titanium oxide to be formed at (or in) the upper surface 106 of the insulating layer 104. In such embodiments, an upper surface 110 of the interface layer 108 may be congruent with the upper surface 106 of the insulating layer 104.

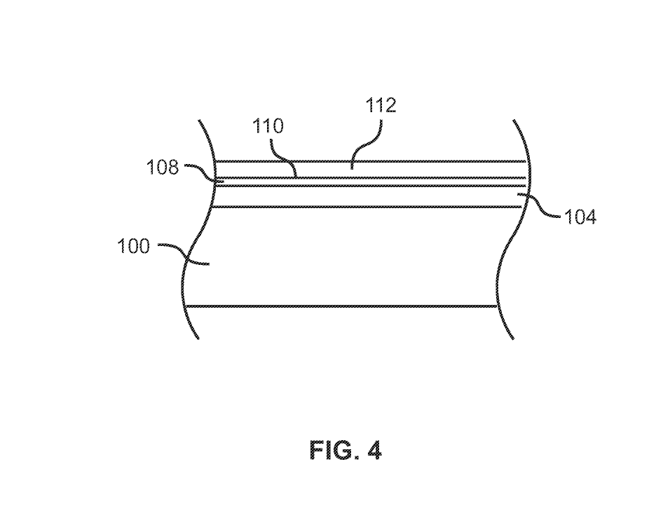

Referring now to FIG. 4, a metallic (or contact) layer 112 is then formed above (e.g., on) the upper surface 110 of the interface layer 108. In some embodiments, the metallic layer 112 includes (or is made of) titanium, titanium nitride, aluminum, or a. combination thereof. The metallic layer may have a thickness of for example, between about 4.0 nm and about 6.0 nm, The metallic layer 112 be formed using any suitable deposition method, such as PVD, ALD, PEALD, CVD, PECVD, or a combination thereof.

The formation of the metallic layer 112 may substantially complete the formation of a MIS contact (e.g., for making an electrical connection to a source of drain region formed within the substrate 100), as is commonly understood.

In some embodiments, the interface layer 108 serves as a barrier between the insulating layer 104 and the metallic layer 112. More specifically, in some embodiments, the interface layer 108 prevents the material of the metallic layer 112 from reacting with the material of the insulating layer 104 if the materials tend to react with one another. For example, in some embodiments, the insulating layer 104 includes (or is made of) titanium oxide and the metallic layer 112 includes titanium. In such embodiments, if the titanium of the metallic layer 112 is deposited directly on the titanium oxide of the insulating layer 104, the titanium may react with the titanium oxide, thus resulting in the de-pinning of the MIS contact ineffective. The inclusion of the interface layer 108, such as one made of titanium nitride (e.g., formed via, deposition) or nitrogen-doped titanium oxide (e.g., formed via a plasma treatment of the insulating layer 104), may prevent this reaction from taking place, and thus preserve the de-pinning effect of the MIS contact.

In some embodiments, the interface layer 108 serves to lower the effective series resistance of the MIS contact. More specifically, in some embodiments, the interface layer 108 decreases the resistance of the MIS contact when the material of the metallic layer 112 is generally not reactive with the material of the insulating layer 104. For example, in some embodiments, the insulating layer 104 includes (or is made of) titanium oxide and the metallic layer 112 includes titanium nitride, nickel, or a combination thereof in such embodiments, if the titanium nitride and/or nickel of the metallic layer 112 is deposited directly on the titanium oxide of the insulating layer 104, the effective series resistance of the MIS contact may be undesirably high. The inclusion of the interface layer 108, such as one made of titanium, aluminum, or a combination thereof, may lower the effective series resistance of the MIS contact by, for example, providing a thin layer of material (i.e., the interface layer) which is more reactive with the material of the insulating material 104 than the material of the metallic layer 112.

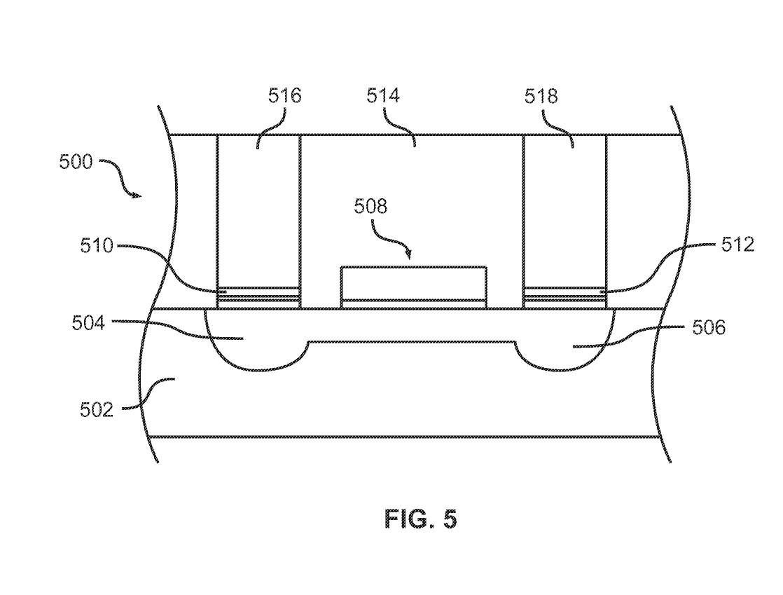

Referring to FIG. 5, the MIS contact(s) described above may be used to form a semiconductor device 500. In some embodiments, the semiconductor device 500 is a metal-oxide-semiconductor field-effect transistor (MOS FET) In the depicted embodiment, the device 500 is formed above, or on, a substrate 502, such as those described above (e.g., a semiconductor substrate). The device 500 includes a source region 504, a drain region 506, and a gate stack 508 formed between the source region 504 and the drain region 506. The source region 504 and the drain region 506 may be formed in the substrate via, for example, implanting (or doping) N-type (or P-type) impurities into the substrate 502, and as shown, may diffuse through the substrate 502 to a region below the gate stack 504. The gate stack 508 may include a conductive gate (e.g., made of polycrystalline silicon) formed above a gate dielectric later (e.g., silicon oxide), both of which may be formed using conventional processes (e.g., PVD, etc.).

The device 500 also includes contacts 510 and 512 respectively formed above the source region 504 and the drain region 506. The contacts 510 and 512 may be MIS contacts formed in a manner similar to that described above (e.g., after the formation of the source region 504 and the drain region 506). Further, the device 500 includes a dielectric material (e.g., an interlayer dielectric layer) 514 formed (e.g., via PVD, etc.) above the substrate 500 through which conductive vias (e.g., made of copper) 516 and 518 have been formed, which are electrically connected to the contacts 510 and 512, respectively.

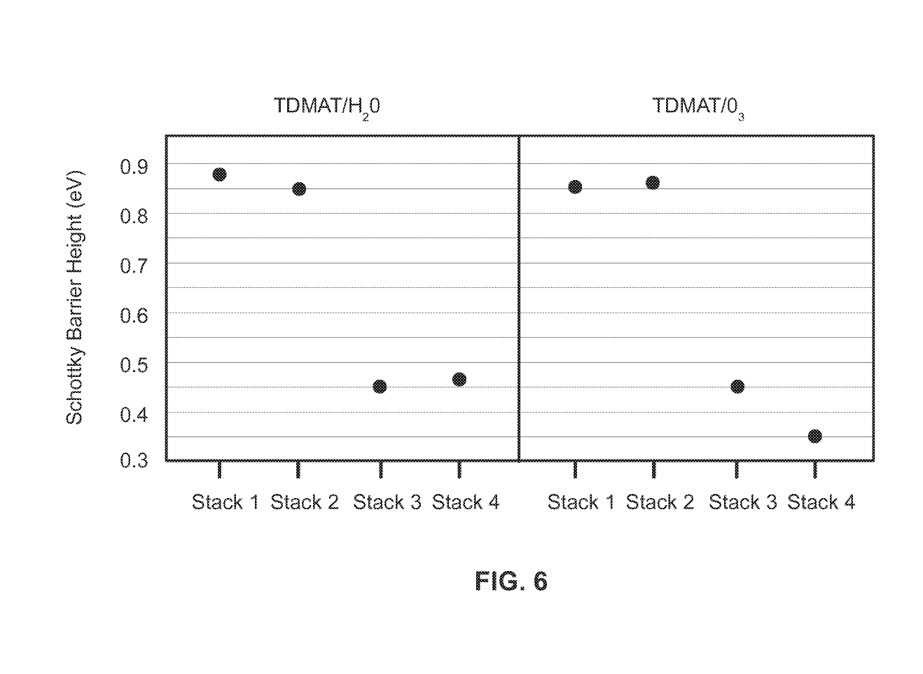

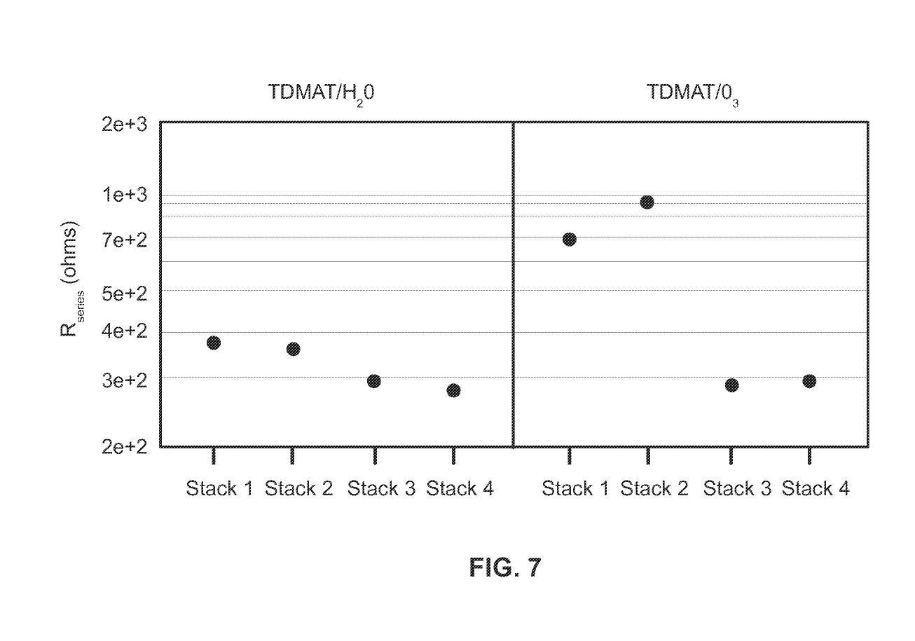

FIGS. 6 and 7 are graphs illustrating data (Schottky barrier height and series resistance, respectively) collected from a series of experiments in which various stacks of materials (i.e., Stacks 1-4, which are the same for both FIGS. 6 and 7), including a titanium oxide layer, were formed using (ND. In both FIGS. 6 and 7, the data on the left side corresponds to stacks in which the titanium oxide was formed using tetrakis(dimethylamino)titanium (TDMAT) as the precursor and water as the oxidant, while the data on the right side corresponds to stacks in which the titanium oxide was formed using TDMAT and ozone (O₃). In Stack 1, a 13 nm thick titanium nitride layer was formed over a 4 nm thick titanium oxide layer. In Stack 2, a 5 nm thick titanium nitride layer was formed over a 8 nm thick nickel layer, which was formed over a 4 nm thick titanium oxide layer. In Stack 3, a 5 nm thick titanium nitride layer was formed over a 8 nm thick titanium layer, which was formed over a 4 nm thick titanium oxide layer. In Stack 4, a 5 nm thick titanium nitride layer was formed over a 8 nm thick titanium-aluminum alloy layer, which was formed over a 4 nm thick titanium oxide layer.

As shown in FIG. 6, the Schottky harrier height is very high (e.g., over 0.85 eV) in stacks (i.e., Stack 1 and Stack 2) in which titanium nitride and nickel (i.e., materials that are relatively non-reactive with titanium oxide) are formed directly on the titanium oxide. The Schottky barrier height remains above 0.45 eV in stacks (i.e., Stacks 3 and 4) in which titanium and titanium-aluminum alloy (i.e., metals that are relatively reactive with titanium oxide) are formed directly on the titanium oxide when water is used as the oxidant. However, when ozone is used as the oxidant, and titanium-aluminum alloy is formed directly on the titanium oxide, the Schottky barrier height drops to about 0.35 eV, which indicates an undesirably low amount of de-pinning.

As shown in FIG. 7, the series resistance of the stacks are lower when materials that are relatively reactive with titanium oxide (i.e., titanium and titanium-aluminum alloy) are formed directly on the titanium oxide, as is the case in Stack 3 and Stack 4. The difference in series resistance is significantly more noticeable when ozone is used as the oxidant.

Thus, based on the data shown in FIGS. 6 and 7, the inclusion of a layer of titanium or titanium-aluminum alloy between the titanium nitride and the titanium oxide may provide a suitably high Schottky barrier height (e.g., above 0.45 eV), while providing reduced series resistance. More particularly, this may be the case for both titanium and titanium-aluminum alloy when water is used as the oxidant, and for titanium when ozone is used as the oxidant.

As a result, in some embodiments, the inclusion of the interface layer allows for metals to be used in MIS contacts which would otherwise not be suitable due to reactivity of those metals with the insulating layer, which often render the de-pinning of the MIS contact ineffective. Also, in some embodiments, the interface layer allows for materials to be used that are not reactive with the insulating layer, but would otherwise result in undesirably high series resistance.

Thus, a wider range of materials may be used in MIS contacts. Additionally, the interface layer may allow a wider range of processes and processing conditions to be used for the formation of the various layers, particularly the insulating layer. Further, the interface layer may improve the adhesion of the metal to the insulating layer.

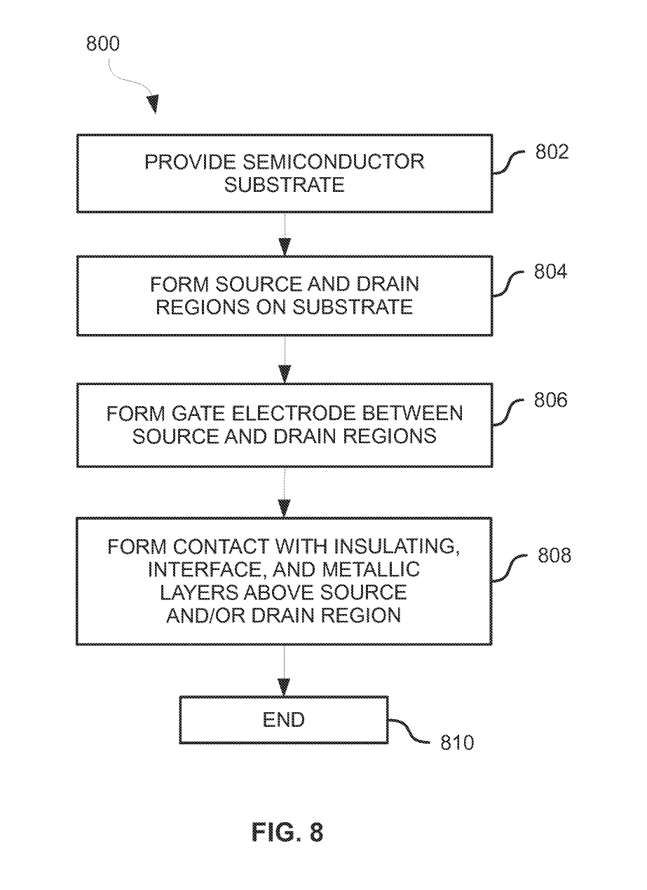

FIG. 8 illustrates a method 800 for forming a semiconductor device according to some embodiments. At block 802, the method 800 begins by providing a substrate, such as a semiconductor substrate as described above.

At block 804, a source region and a drain region are formed on (or in) the substrate. The source region and the drain region may be formed in the substrate via, for example, implanting (or doping) N-type (or P-type) impurities into the substrate, as is commonly understood.

At block 806, a gate electrode (or gate stack) is formed above (or on) the substrate between the source region and the drain region. The gate electrode may include a gate conductor (e.g., made of polycrystalline silicon) formed over a gate dielectric layer (e.g., silicon oxide).

At block 808, a contact is formed over at least one of the source region and the drain region (e.g., a contact may be formed over each). The contact(s) includes an insulating layer, an interface layer formed above the insulating layer, and a metallic (or contact) layer formed above the interface layer.

In some embodiments, the insulating layer includes (or is made of) an insulating material such as metal oxide or a nitride, such as titanium oxide, hafnium oxide, aluminum oxide, zirconium oxide, silicon oxide, silicon nitride, silicon oxynitride, or a combination thereof. The insulating layer may be formed using, for example, PVD, ALD, PEALD, CVD, PECVD, or a combination thereof.

In some embodiments, the interface layer includes (or is made of) titanium, titanium nitride, aluminum, nitrogen-doped titanium oxide, or a combination thereof In some embodiments, the interface layer is formed by depositing a material (e.g., titanium nitride or titanium) on the upper surface of the insulating layer using, for example, PVD, ALD, PEALD, CVD, PECVD, or a combination thereof. In some embodiments, the interface layer is formed by performing a plasma treatment on the upper surface of the insulating layer. An example of such a plasma treatment is an exposure to nitrogen radicals (e.g., using a remote plasma source), which results in a thin layer of nitrogen-doped material (e.g., nitrogen-doped titanium oxide) at the top of the insulating layer.

As described above, in some embodiments, the interface layer serves as a barrier between the insulating layer and the metallic layer, while in some embodiments, the interface layer serves to lower the effective series resistance between the insulating layer and the metallic layer.

The metallic layer includes (or is made of) titanium, titanium nitride, aluminum, or a combination thereof and may be formed using any suitable deposition method, such as PVD, ALD, PEALD, CVD, PECVD, or a combination thereof. In some embodiments, the insulating layer, the interface layer, and the metallic layer jointly form a MIS contact. As described above, additional processing steps may be performed on the substrate to complete the formation of a semiconductor device (e.g., a MOSFET), such as the formation of a dielectric layer above the substrate and the formation of conductive vias extending through the dielectric layer. At block 810, the method 800 ends.

Thus, in some embodiments, semiconductor devices and methods for forming a semiconductor device are provided. A semiconductor substrate is provided. A source region and a drain region are formed on the semiconductor substrate. A gate electrode is formed between the source region and the drain region. A contact is formed above at least one of the source region and the drain region. The contact includes an insulating layer formed above the semiconductor substrate, an interface layer formed above the insulating layer, and a metallic layer formed above the interface layer. The interface layer is operable as a barrier between a material of the insulating layer and a material of the metallic layer, reduces the electrical resistance between the material of the insulating layer and the material of the metallic layer, or a combination thereof.

In some embodiments, semiconductor devices and methods for forming semiconductor device are provided. A semiconductor substrate is provided. A source region and a drain region are formed on the semiconductor substrate. A gate electrode is formed between the source region and the drain region. A contact is formed above at least one of the source region and the drain region. The contact includes an insulating layer formed above the semiconductor substrate. The insulating layer includes titanium oxide. An interface layer is formed above the insulating layer. The interface layer includes at least one of titanium nitride, nitrogen-doped. titanium oxide, nickel, or a combination thereof. A metallic layer is formed above the interface layer. The metallic layer includes titanium. The interface layer is operable as a barrier between a material of the insulating layer and a material of the metallic layer

In some embodiments, semiconductor devices and methods for forming a semiconductor device are provided. A semiconductor substrate is provided. A source region and a drain region are formed on the semiconductor substrate. A gate electrode is formed between the source region and the drain region. A contact is formed above at least one of the source region and the drain region. The contact includes an insulating layer formed above the semiconductor substrate. The insulating layer includes titanium oxide. An interface layer is formed above the insulating layer. The interface layer includes at least one of titanium, aluminum, or a combination thereof. A metallic layer is formed above the interface layer, The metallic layer includes at least one of titanium nitride, nickel, or a combination thereof. The interface layer reduces the electrical resistance between the material of the insulating layer and the material of the metallic layer.

Although the foregoing examples have been described in some detail for purposes of clarity of understanding, the invention is not limited to the details provided. There are many alternative ways of implementing the invention. The disclosed examples are illustrative and not restrictive.

1. A method for forming a semiconductor device, the method comprising:
providing a semiconductor substrate;
forming a source region and a drain region on the semiconductor substrate;
forming a gate electrode between the source region and the drain region; and
forming a contact above at least one of the source region or the drain region,
wherein the contact comprises an insulating layer formed above the semiconductor substrate, an interface layer formed above and directly interfacing the insulating layer, and a metallic layer formed above the interface laver,
wherein the interface layer comprises at least one of titanium nitride, nitrogen-doped titanium oxide, or a combination thereof,
wherein the at least one of titanium nitride, nitrogen-doped titanium oxide, or the combination thereof directly interfaces the insulating layer, and
wherein the interface layer is operable as a barrier between a material of the insulating layer and a material of the metallic layer, reduces the electrical resistance between the material of the insulating layer and the material of the metallic layer, or a combination thereof.

2. The method of claim 1, wherein the insulating layer comprises a metal oxide.

3. The method of claim 2, wherein the insulating layer comprises titanium oxide.

4. The method of claim 3, wherein the interface layer has a thickness of between about 0.1 nanometers (nm) and about 2.0 nm.

5. The method of claim 4, wherein the interface layer is operable as a barrier between the material of the insulating layer and the material of the metallic layer.

6. The method of claim 1, wherein the interface layer comprises nitrogen-doped titanium oxide.

7. The method of claim 5, wherein the metallic layer comprises titanium.

8. The method of claim 4, wherein the interface layer reduces the electrical resistance between the material of the insulating layer and the material of the metallic layer.

9. The method of claim 8, wherein the interface layer comprises at least one of titanium, aluminum, or a combination thereof.

10. The method of claim 9, wherein the metallic layer comprises at least one of titanium nitride, nickel, or a combination thereof.

11-15. (canceled)

16. A method for fanning a semiconductor device, the method comprising:
providing a semiconductor substrate;
forming a source region and a drain region on the semiconductor substrate;
forming a gate electrode between the source region and the drain region; and
forming a contact above at least one of the source region and the drain region,
wherein the contact comprises:
an insulating layer formed above the semiconductor substrate,
wherein the insulating layer comprises titanium oxide;
an interface layer formed above the insulating layer,
wherein the interface layer comprises at least one of titanium nitride, nitrogen-doped titanium oxide, or a combination thereof, and
wherein the at least one of titanium nitride, nitrogen-doped titanium oxide, or a combination thereof directly interfaces titanium oxide of the insulating layer;
a metallic layer formed above the interface layer,
wherein the metallic layer comprises at least one of titanium nitride, nickel, or a combination thereof.

17. The method of claim 16, wherein the interface layer has a thickness of between about 0.1 nanometers (nm) and about 2.0 nm.

18. The method of claim 17, wherein the insulating layer has a thickness of between about 3.0 nm and about 5.0 nm.

19. The method of claim 18, wherein the metallic layer has a thickness of between about 4.0 nm and about 6.0 nm.

20. The method of claim 19, wherein the interface layer is formed using at least one of physical vapor deposition (PVD), atomic layer deposition (ALD), plasma-enhanced atomic layer deposition (PEALD), chemical vapor deposition (CVD), plasma-enhanced chemical vapor deposition (PECVD), a plasma treatment or a combination thereof.

21. The method of claim 1, wherein the interface layer comprises titanium nitride.

22. The method of claim 2, wherein the insulating layer comprises at least one of hafnium oxide, aluminum oxide, zirconium oxide, silicon oxide, silicon nitride, silicon oxynitride, or a combination thereof.

23. The method of claim 1, wherein the interface layer is formed by plasma treating the insulating layer.

24. The method of claim 23, wherein the interface layer is formed by exposing titanium oxide of the insulating layer to nitrogen radicals.

25. The method of claim 24, wherein the metallic layer comprises titanium.
